(19) United States
(12) Patent Application Publication
(10) Pub. No.: US 2008/0211058 A1
(43) Pub. Date: Sep. 4, 2008

(54) Semiconductor device and method of manufacturing same

(75) Inventors: Shintaro Asano, Tokyo (JP); Kazutoshi Fukahori, Tokyo (JP); Shinichi Miyatake, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/007,844

(22) Filed: Jan. 16, 2008

(30) Foreign Application Priority Data
Jan. 17, 2007 (JP) 2007-007962

(51) Int. Cl. H01L 21/441; H01L 29/86

(52) U.S. Cl. 257/529; 438/601; 257/E29.325; 257/E21.476

(57) ABSTRACT

A semiconductor device comprises one or more elements subjected to trimming, formed on a main surface side of a silicon substrate and that is/are to be laser trimmed, and an electrode lead of the element subjected to trimming disposed below the position of the element subjected to trimming. The electrode lead subjected to trimming comprises a diffusion layer formed in an uppermost layer of the silicon substrate. The diffusion layer is covered with a protection film made of doped polysilicon and is directly formed on the silicon substrate.

This application is based upon and claims the benefit of priority from Japanese patent application No. 2007-7962, filed on Jan. 17, 2007, the disclosure of which is incorporated herein in its entirety by reference.

### BACKGROUND OF THE INVENTION

1. Field of the Invention

The present invention relates to a semiconductor device which comprises a laser trimmed element and electrode leads arranged on an underlying layer of the element and connected to terminals of the element.

2. Description of the Related Art

Conventionally, in the manufacturing of semiconductor devices, laser trimming is often performed for blowing or partially removing fuses, thin film resistors and the like by irradiating them with a laser beam in order to adjust the performance of a finished device. A semiconductor device which undergoes such laser trimming is structured such that a laser beam irradiated on fuses and the like does not damage wiring patterns, transistor elements and the like which may exist below the position of the fuses and the like.

For example, in a semiconductor device shown in Japanese Patent Application Laid-open No. 2005-19498A (hereinafter called Cited Document 1), a linear wire mainly made of tungsten, a planar common line mainly made of titanium nitride or polysilicon, and a fuse mainly made of aluminum are formed on a substrate in this order through inter-layer films. One end of the fuse is connected to the common line through a throughhole, while the other end of the fuse is connected to an end of the linear wire through a throughhole extending through a hole formed through the planar common line. According to such a configuration, the linear wire is covered with the planar common line, so that the linear wire can be prevented from being damaged by a laser beam which is irradiated on a fuse in order to blow the fuse.

In a semiconductor device shown in Japanese Patent Application Laid-open No. 2005-251822A (hereinafter called Patent Document 2), a first layer insulating film, a first layer wiring pattern, a second layer insulating film, a second layer wiring pattern, a third layer insulating film, and a thin film resistor are laminated in this order on a main surface of a silicon substrate. The thin film resistor has both ends electrically connected to the second layer wiring pattern through throughholes. The second layer wiring pattern comprises a metal material pattern and a refractory metal formed on the surface of the metal material pattern, where part of the second layer wiring pattern extends into a region below the thin film resistor to constitute laser beam blocking film. In such a configuration, since the laser beam blocking film is present between the thin film resistor and silicon substrate in the region below the thin film resistor, a laser beam used for laser trimming is reflected by the laser beam blocking film in a direction opposite to the silicon substrate, thus making it possible to prevent the laser beam from being irradiated onto the silicon substrate.

However, in the semiconductor device shown in Patent Document 1, the planar common line is formed with an opening through which the end of the fuse is connected to the end of the linear wire through the throughhole. Thus, the laser beam for blowing the fuse is likely to pass through the opening so that the diffusion layer of the silicon substrate is also irradiated with the laser beam.

Patent Document 2, in turn, simply discloses that the laser beam blocking film, having the refractory metal formed on the surface of the metal material of the wiring pattern, is disposed inside a layer which forms from the thin film resistor to the silicon substrate. There is no any suggestion that the laser beam blocking layer is formed so as not to expose the diffusion layer on the surface of the silicon substrate.

Therefore, in either of the related arts, the laser beam for blowing a fuse is likely to be irradiated onto the diffusion layer on the surface of the silicon substrate. When this diffusion layer is irradiated with a laser beam which has thermal energy high enough to blow the fuse, a thermal diffusion will cause crystal defects to be produced in a PN junction, resulting in a phenomenon in which a current leaks from the crystal defects of the PN junction (hereinafter called “junction leak”),—this phenomenon has been found by the inventors.

The mechanism that causes this problem will be described with reference to an exemplary configuration of a semiconductor device which has a fuse. FIGS. 1A, 1B and FIG. 2 show a process from fuse blowing to junction leak.

In the configuration of a semiconductor device which can suffer from the foregoing problem, aluminum fuse 1 made of an aluminum material is exposed on the surface of the semiconductor device, as shown in FIGS. 1A, 1B. Aluminum fuse 1 has both ends connected to tungsten 3 through underlying throughholes 2, respectively. Further, each tungsten 3 is connected to the end of a conductor made of N-type diffusion layer 6 on the surface of P-type silicon substrate (P-sub) 5 through contact 4 on an underlying layer. In other words, diffusion layer 6 which extends in one direction on the topmost layer of silicon substrate 5 is used for electrode leads of the fuse. Then, a plurality of aluminum fuses 1, which are arranged in this way, are disposed adjacent to the surface of the semiconductor device.

On the other hand, laser beam 7 irradiated on aluminum fuses 1 is adjusted to produce laser spot 8 having a diameter slightly larger than aluminum fuses 1 in order to blow the fuses without fail.

Aluminum fuse 1 is heated to the melting point of the aluminum material by laser beam 7 irradiated thereto, and is thereby instantaneously blown. Laser beam 7 is focused such that its thermal energy reaches the highest value near the fuse. However, beyond the focal point, a leaking laser beam increasingly expands through an inter-layer film, with its thermal energy reaching silicon substrate 5. Dotted line P in FIG. 1A indicates the diameter beyond the laser spot.

When this thermal energy is irradiated onto diffusion layer 6 which is the electrode lead of aluminum fuse 1 adjacent to the fuse region irradiated with laser beam 7, crystal defect 12 occurs in a PN junction due to thermal diffusion. Specifically, crystal defect 11 originally produced in diffusion layer 6 during a diffusion process reaches P-type silicon substrate 5 through the PN junction in a chain manner to reduce the resistance of a junction surface, thereby resulting in junction leak (current leak) 13 (FIG. 2).

For example, when one of the fuse electrodes is connected to a fuse latch circuit, and the other is connected to minus power supply VSS such as ground, the fuse latch circuit determines whether or not the fuse has been blown by sensing “VSS connected” or “floating state” from a current flowing through the latch circuit or the resistance of the same. However, when the junction leak causes the flowing current or resistance to be halfway between “VSS connection” and “floating state,” the latch circuit will introduce a malfunction due to erroneous determination.

To prevent this phenomenon, distance B is provided between adjacent fuses to such a degree or more that the junction leak does not occur even if laser beam 7 is irradiated on fuse 3 to be blown, as shown in FIGS. 1A, 1B, based on data of the results from a laser irradiation experiment and the like. This required distance causes a reduction in the degree to which the fuse can be integrated. This further leads to an increase in chip area.

### SUMMARY OF THE INVENTION

It is an exemplary object of the present invention to prevent an increase in crystal defects caused by the irradiation of a laser beam for use in laser trimming to restrain a current leak in a PN junction, regarding the impurity diffusion layer of a silicon substrate. It is another object to improve the degree to which elements, such as fuses, which undergo the laser trimming, can be integrated.

The present invention relates to a semiconductor device that comprises one or more elements subjected to trimming that is/are to be laser trimmed, formed on the main surface side of a silicon substrate, and an electrode lead of the element subjected to trimming that is disposed below the position of the element subjected to trimming.

In this semiconductor device, the electrode lead of the element subjected to the trimming comprises a diffusion layer formed in the uppermost layer of the silicon substrate. Then, the diffusion layer is covered with a protection film made of doped polysilicon and is directly formed on the silicon substrate, thereby solving the aforementioned problem.

The above and other objects, features and advantages of the present invention will become apparent from the following description with reference to the accompanying drawings which illustrate examples of the present invention.

### BRIEF DESCRIPTION OF THE DRAWINGS

FIG. 1A is a plan perspective view showing a semiconductor device according to the related art;

FIG. 1B is a cross-sectional view schematically showing the semiconductor device according to the related art;

FIG. 2 is a schematic diagram for describing a problem of the related art with reference to an enlarged cross-section of part A in FIG. 1B;

FIG. 3A is a plan perspective view for describing a problem of the related art;

FIG. 3B is a schematic cross-sectional view for describing a problem of the related art;

FIG. 4A is a plan perspective view showing the basic configuration of a semiconductor device according to the present invention;

FIG. 4B is a schematic cross-sectional view of the basic configuration of the semiconductor device according to the present invention;

FIG. 5 is a diagram for describing actions of the present invention with reference to an enlarged cross-section of part C in FIG. 4B;

FIG. 6A is a plan perspective view of a device for describing effects of the present invention;

FIG. 6B is a schematic cross-sectional view of the device for describing effects of the present invention;

FIG. 7 is a diagram for describing a situation in which crystal defects occur due to a difference in the impurity concentration of the diffusion layer;

FIG. 8 is a diagram for describing a situation in which crystal defects occur due to a difference in impurity concentration of the diffusion layer;

FIG. 9A is a plan perspective view showing another exemplary embodiment of the present invention; and

FIG. 9B is a schematic cross-sectional view showing the other exemplary embodiment of the present invention.

### DESCRIPTION OF THE EXEMPLARY EMBODIMENT

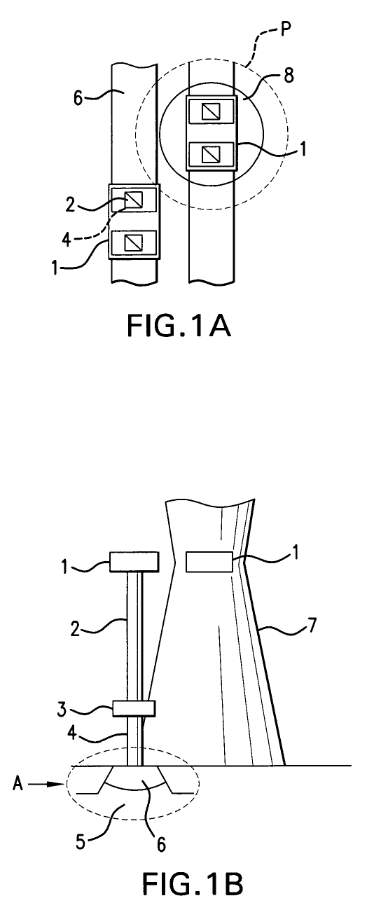

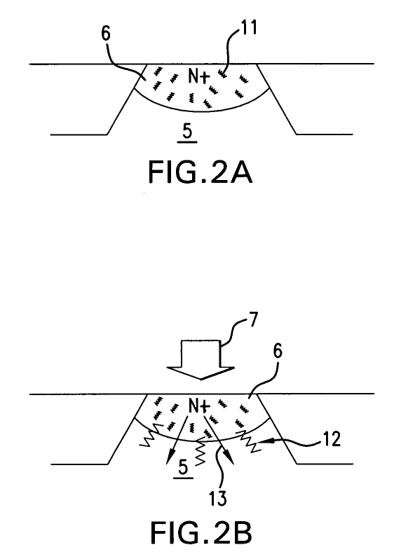

Here, a description will be given using an exemplary configuration of the semiconductor device having a fuse, shown in FIGS. 1A, 1B, where the same components as those in the figures are designated the same reference numerals.

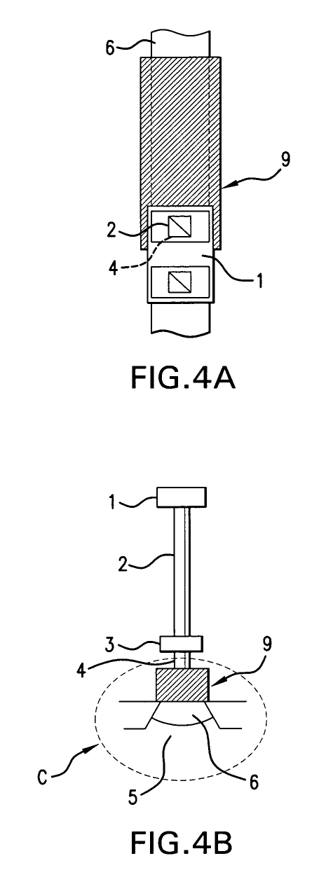

FIG. 4A is a plan perspective view showing the basic configuration of a semiconductor device according to the present invention, and FIG. 4B is a schematic cross-sectional view of the same. As shown in these figures, diffusion layer 6 which is an electrode lead of aluminum fuse 1 is directly covered with protection film 9. Doped polysilicon is used for the material of protection film 9.

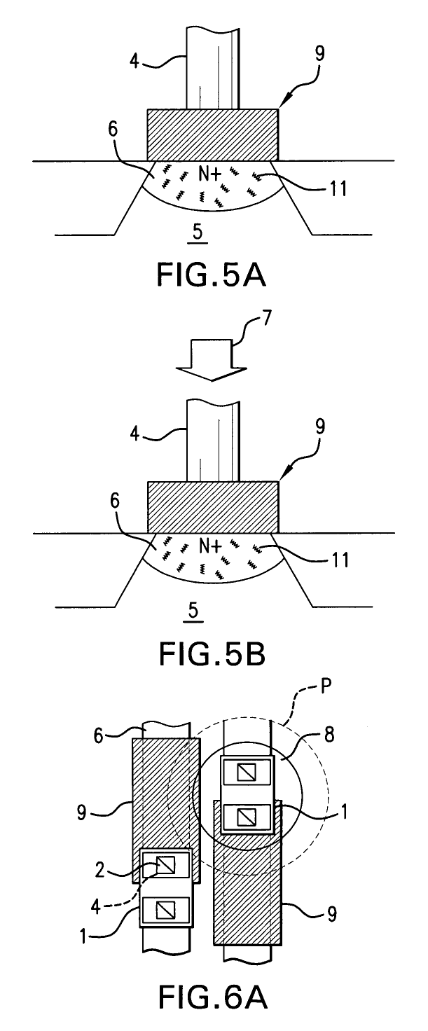

Further, actions of the semiconductor device shown in FIGS. 4A, 4B will be described with reference to FIG. 5.

Protection film 9 is formed of doped polysilicon doped with impurities in the uppermost portion of P-type silicon substrate 5 which is formed with relatively high concentration N+-type diffusion layer 6. Since protection film 9 made of doped polysilicon is irradiated with laser beam 7 which leaks downward around a fuse subjected to laser trimming, laser beam 7 is shielded by protection film 9, so that laser beam 7 hardly reaches diffusion layer 6.

In this way, thermal energy by laser beam 7 is hardly transferred to diffusion layer 6, thus making it possible to prevent the occurrence of crystal defects due to the heat of laser beam 7. As a result, crystal defect 11 which has been produced in a diffusion process during the formation of the diffusion layer will never reach P-type silicon substrate 5 through a PN junction, thus making it possible to prevent current leakage in the PN junction.

Generally, the melting point of aluminum material is 660° C. Typically, the energy amount, the irradiated spot diameter, and the irradiation time of the laser beam are controlled to such a degree that only fuse 1 made of the aluminum material melts. On the other hand, the melting point of polysilicon is 1400° C., which is approximately twice as high as 660° C. of the aluminum material. Therefore, even if the laser beam is irradiated onto the polysilicon, the polysilicon will not be melted.

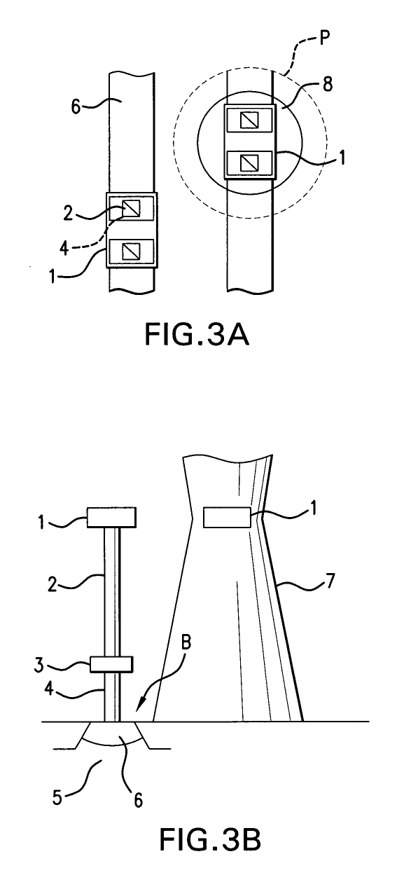

As described above, in the present invention, diffusion layer 6 which is the electrode lead of aluminum fuse 1 is directly covered with protection film 9 made of polysilicon. Therefore, when diffusion layer 6 exists, as disposed for use as the electrode lead of another aluminum fuse 1 in a region around and below an element such as aluminum fuse 1 subjected to laser trimming, as shown in FIGS. 3A, 3B, laser beam 7 is shielded by protection film 9 even if it leaks to the region around and below the element subjected to laser trimming, so that diffusion layer 6 is not irradiated with laser beam 7. As a result, no current leak occurs in the PN junction of diffusion layer 6.

From the foregoing, it is not necessary to set the interval between adjacent elements subjected to laser trimming to a distance equal to or larger than that which prevents the junction leak, as required in the related art. As a result, it is possible to increase the degree to which elements such as fuses, thin film resistors and the like, subjected to laser trimming, can be integrated.

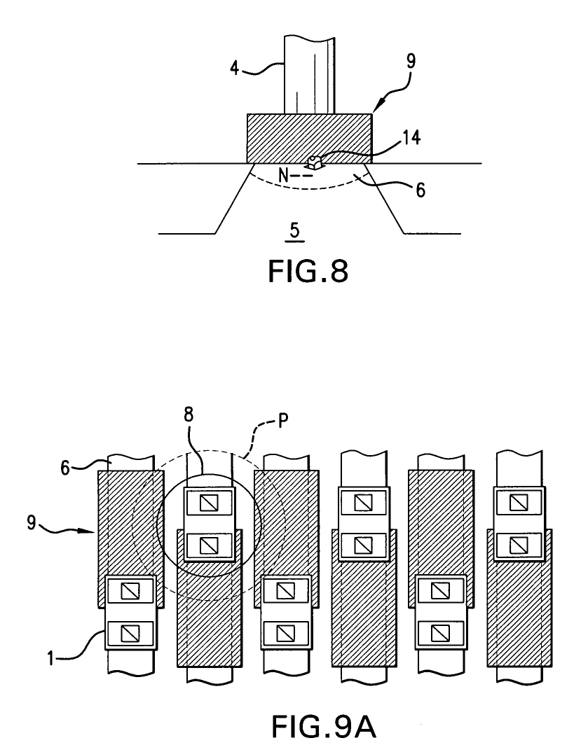

Also, because the concentration of impurities in diffusion layer 6 is lower, fewer crystal defects occur due to the thermal energy of the laser beam, thus providing the effects of the present invention. This is described with reference to FIGS. 7 and 8. FIG. 7 shows an example in which N−-type diffusion layer 6 is formed through ion implantation but in a concentration lower than that mentioned above. In this event, crystal defects 11 produced in a diffusion process during the formation of the diffusion layer exist only in a shallower region, as compared with an N+-type diffusion layer, leading to a lower rate of crystal defects caused by the heat of the laser beam. On the other hand, FIG. 8 shows the configuration which includes N−-type diffusion layer 6 formed without ion implantation. In the configuration of FIG. 8, since the factor which causes crystal defects in diffusion layer 6 is only heat 14 in the diffusion process during the formation of doped polysilicon, crystal defects hardly exist. Thus, crystal defects due to the heat of the laser beam are extremely unlikely to occur. From the foregoing, the occurrence of junction leaks due to the irradiation of the laser beam can be reduced because the impurity concentration of diffusion layer 6 is lower.

The semiconductor device described above is manufactured in the following manner. Diffusion layer 6 is formed in the uppermost layer of silicon substrate 5 as an electrode lead of aluminum fuse 1. Protection film 9 made of doped polysilicon including polysilicon doped with impurities is produced on diffusion layer 6. At least an inter-layer film is formed on silicon substrate 5 including the doped polysilicon to form throughhole 2, tungsten 3, contact 4 and the like in the inter-layer film. Aluminum fuse 1 is formed on the inter-layer film, and an end of aluminum fuse 1 is connected to an upper end of throughhole 2.

When the semiconductor device according to such a manufacturing method is, for example, a DRAM, protection film (doped polysilicon) 9 which directly covers part of diffusion layer 6 on the uppermost layer of silicon substrate 5 can be produced in a polysilicon producing process (for example, a cell contact manufacturing process for a memory cell array) in an existing DRAM manufacturing process. In addition, existing DRAM manufacturing processes can be applied to processes other than the formation of protection film (doped polysilicon) 9.

Next, another embodiment is shown.

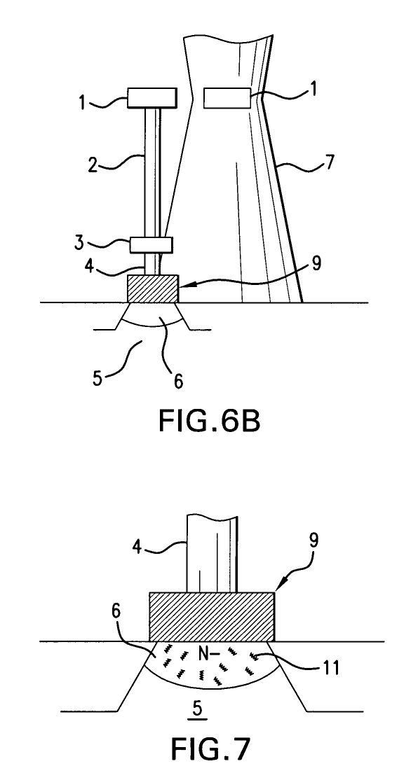

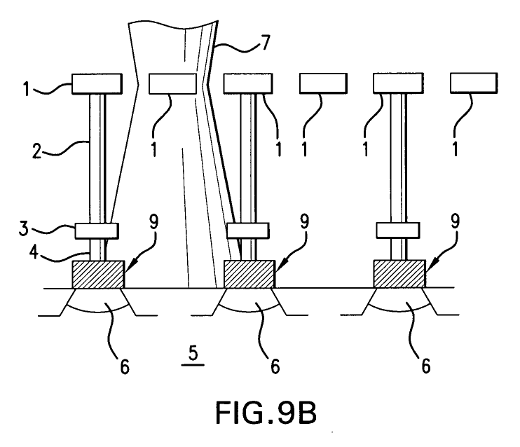

FIGS. 9A, 9B show an example in which a plurality of the basic configuration shown in FIGS. 4A, 4B are arranged. As shown in FIGS. 9A, 9B, even when a plurality of aluminum fuses 1 are arranged in close proximity at a high density, it is possible to prevent the occurrence of crystal defects in diffusion layer 6 which is the electrode lead of aluminum fuse 1, due to irradiation of the laser beam, to present leak current. Also, since the present invention is characterized by increasing the degree to which elements such as fuses, subjected to laser trimming, can be integrated, the present invention provides larger effects because a larger number of elements subjected to laser trimming are arranged, as shown in FIG. 6A.

While each of the embodiments described above has shown a semiconductor device which comprises a metal fuse that can be blown by a laser beam, the element subjected to laser trimming is not limited to the metal fuse, but may be a resistive element. Thus, other than the semiconductor device which has a plurality of aluminum fuses 1 arranged at a high density, for example, as shown in FIG. 9B, the present invention can also be applied to a semiconductor device which has fuses and resistors arranged on the surface side of the semiconductor device at a high density.

As illustrated above, according to the present invention, the protection film (doped polysilicon) directly covers the diffusion layer of the silicon substrate which is disposed as an electrode lead in a region around and below an element such as a fuse subjected to trimming. By doing so, it is possible to prevent the occurrence of crystal defects in the diffusion layer due to the irradiation of the laser beam to prevent leak current in the PN junction. As a result, it is also possible to improve the degree to which elements subjected to laser trimming can be integrated.

Specifically, when a diffusion layer exists, as disposed as an electrode lead of another element in a region around and below an element subjected to trimming, even if a laser beam leaks to the region around and below the element subjected to trimming, the heat of the laser beam will barely reach the diffusion layer covered with the doped polysilicon which is a protection layer, as required in the related art. As a result, no current leakage occurs in the PN junction of the diffusion layer. From the foregoing, it is not necessary to set the interval between adjacent elements subjected to laser trimming to a distance equal to or larger than that which prevents the junction leak. As a result, it is possible to increase the degree to which elements such as fuses, thin film resistors and the like, subjected to laser trimming, can be integrated.

While preferred embodiments of the present invention have been described using specific terms, such description is for illustrative purposes only, and it is to be understood that changes and variations may be made without departing from the spirit or scope of the following claims.

What is claimed is:

1. A semiconductor device comprising:
one or more elements subjected to trimming, formed on a main surface side of a silicon substrate and to be laser trimmed; and
an electrode lead of said element subjected to trimming disposed below the position of said element subjected to trimming,
wherein said electrode lead comprises a diffusion layer formed in an uppermost layer of said silicon substrate, and
said diffusion layer is covered with a protection film directly formed on said silicon substrate.

2. The semiconductor device according to claim 1, wherein said protection film comprises doped polysilicon including polysilicon doped with impurities.

3. The semiconductor device according to claim 1, wherein the melting point of said protection film is higher than the melting point of said element subjected to trimming.

4. The semiconductor device according to claim 1, wherein said element subjected to trimming is a metal fuse.

5. A method of manufacturing a semiconductor device comprising one or more elements subjected to trimming, formed on a main surface side of a silicon substrate and that are to be laser trimmed, and an electrode lead of said element subjected to trimming disposed below the position of said element subjected to trimming, said method comprising the steps of:
forming said electrode lead with a diffusion layer formed in an uppermost layer of said silicon substrate;
covering said diffusion layer with doped polysilicon including polysilicon doped with impurities;
forming at least an inter-layer film on said silicon substrate including said doped polysilicon;
forming an electric contact on said inter-layer film; and
forming said element subjected to trimming on said inter-layer film, and connecting an end of said element subjected to trimming to an upper end of said electric contact.
